(19) United States
(12) Patent Application Publication
(10) Pub. No.: US 2024/0147667 A1
(43) Pub. Date: May 2, 2024

(54) LIQUID-COOLING HEAT-DISSIPATING MODULE WITH EMBEDDED THREE-DIMENSIONAL VAPOR CHAMBER DEVICE

(71) Applicant: GUANGZHOU NEOGENE THERMAL MANAGEMENT TECHNOLOGY CO., LTD., GUANGZHOU (CN)

(72) Inventor: JEN-SHYAN CHEN, GUANGZHOU (CN)

(21) Appl. No.: 18/333,762

(22) Filed: Jun. 13, 2023

(30) Foreign Application Priority Data
Oct. 31, 2022 (CN) 202211344126.1
Nov. 8, 2022 (CN) 202222972384.6
Dec. 21, 2022 (CN) 202223436765.9
Feb. 17, 2023 (CN) 2023101313568

(51) Int. Cl. H05K 7/20

(52) U.S. Cl. CPC H05K 7/20336; H05K 7/20409

(57) ABSTRACT

A liquid-cooling heat-dissipating module with embedded three-dimensional vapor chamber device comprises a three-dimensional vapor chamber device and a semi-open case. The three-dimensional vapor chamber device comprises an upper cover having a base plate and a tube, a bottom cover and a porous wick structure. The base plate has a base cavity and an opening hole. The tube is configured on an upper outer surface, located above the opening hole and extended outwardly. An airtight cavity is formed from a tubular cavity of the tube and the base cavity when the bottom cover is sealed to the upper cover. The porous wick structure is formed continuously on a tubular internal surface, an upper internal surface and a bottom internal surface. The semi-open case has an inlet and an outlet, and is coupled to the bottom cover to form a heat-exchanging chamber. The inlet and outlet are connected to the heat-exchanging chamber.

### BACKGROUND OF THE INVENTION

### 1. Field of the Invention

The present invention relates to a liquid-cooling heat-dissipating module, and more particularly, to a liquid-cooling heat-dissipating module with embedded three-dimensional vapor chamber device.

### 2. Description of the Prior Art

With the rapid changes in technology, various high-performance electronic products are designed and developed for widely used to meet the needs of modern people's daily life as well as commercial and industrial development. Currently, the rapid development of semiconductor chips for data center servers and in-vehicle autonomous driving artificial intelligence has led to the development of chips with higher computing power and higher density. This means the heat and power consumption of electronic chips per unit volume or unit area will increase dramatically. The traditional air-cooling forced convection technology will not be able to meet the heat dissipation needs of some integrated circuit (IC) electronic components, and water-cooling heat dissipation technology will become the mainstream solution for heat dissipation with high heat flux.

A water-cooling device in the field of water-cooling heat dissipation technology of the prior art is contacted with a heating electronic components through a water-cooling plate metal case of the heat-exchanging chamber in the water-cooling device. Moreover, the water-cooling device can increase the area of heat dissipation through the micro-channel structure disposed in water-cooling plate metal case. The heating electronic component transfers heat to the micro-channel structure through the water-cooling plate metal case through heat conduction, and heat exchange with the water stream to indirectly carry away the heat power consumption of the electronic components. In addition, the water-cooling device of the prior art mainly transfers high energy density heat to the micro-channel in the heat-exchanging chamber through an aluminum metal case or a copper metal case by heat conduction, and then exchanges heat with the cold liquid fluid in the heat-exchanging chamber. As the power for the chip with high-intensity computing is increasing, the demand for heat dissipation continues to increase, and the demand for water-cooling device that reduce the thermal resistance of heat conduction paths is expected to be urgent in the industry. Under the aforementioned conditions, more efficient heat dissipator technology with water-cooling is needed to solve the problem of cooling and heat dissipation for chips with high performance.

### SUMMARY OF THE INVENTION

Therefore, the present invention provides a liquid-cooling heat-dissipating module with embedded three-dimensional vapor chamber device to solve the problems of the prior art.

The present invention provides a liquid-cooling heat-dissipating module with embedded three-dimensional vapor chamber device, comprising a three-dimensional vapor chamber device and a semi-open case. The three-dimensional vapor chamber device comprises an upper cover, a bottom cover, a porous wick structure and a working fluid. The upper cover has a base plate and a tube. The base plate has a base cavity, an opening hole, an upper outer surface and an upper inner surface. The tube has a tubular cavity and a tubular internal surface. The tube is configured on the upper outer surface, located above the opening hole and extended outwardly. The bottom cover corresponding to the upper cover has a bottom internal surface and a bottom outer surface. An airtight cavity is formed from the base cavity and the tubular cavity when the bottom cover is sealed to the upper cover. The bottom outer surface of the bottom cover is configured to be contacted with a heat source. The porous wick structure is continuously disposed on the tubular internal surface, the upper internal surface and the bottom internal surface. The working fluid is configured in the airtight cavity, and the pressure of the airtight cavity is less than 1 atm. The semi-open case has an inlet and an outlet. The semi-open case is coupled to the bottom cover of the three-dimensional vapor chamber device to form a heat-exchanging chamber. The inlet and the outlet are connected to the heat-exchanging chamber.

Wherein, the tube further has a top end having a sealed structure, the sealed structure is formed by pre-setting a liquid injection port at the top end, and injecting the working fluid into the airtight cavity through the liquid injection port, and then sealing the liquid injection port.

Wherein, a cold liquid fluid is configured in the heat-exchanging chamber, the inlet and the outlet, and the cold liquid fluid is selected from the group consisting of water, acetone, ammonia, methanol, tetrachloroethane, and hydrofluorocarbon chemical refrigerants.

Wherein, the bottom cover has a plurality of grooves, and a groove rib is formed between the grooves, the groove rib has a rib surface, and each of the grooves has a groove internal surface and a groove cavity.

Wherein, the porous wick structure is continuously disposed on the upper internal surface, the bottom internal surface, the tubular internal surface, the rib surface of the groove rib and the groove internal surfaces.

Wherein, the three-dimensional vapor chamber device further comprises a plurality of heat dissipation fins, the tube further comprises a condenser area, and the heat dissipation fins are coupled to the condenser area of the tube.

Wherein, the porous wick structure is disposed by pre-laying a copper-containing powder on the upper internal surface, the bottom internal surface and the tubular internal surface, and after the heat dissipation fins are disposed on the condenser area of the tube, the porous wick structure is continuously disposed on the tubular internal surface, the upper internal surface and the bottom internal surface and the heat dissipation fins are coupled to the condenser area simultaneously by the same sintering process.

Wherein, the three-dimensional vapor chamber device further comprises a plurality of support columns disposed between the upper internal surface of the base plate and the bottom internal surface of the bottom cover, each of the support columns has a column surface, and the porous wick structure continuously disposed on the upper internal surface, the bottom internal surface, the tubular internal surface and the column surface.

Wherein, the bottom cover further comprises a bottom groove configured to accommodate a circuit board with a chip, a chip surface of the chip is contacted with a bottom groove surface of the bottom groove.

The present invention provides another liquid-cooling heat-dissipating module with embedded three-dimensional vapor chamber device, comprising a three-dimensional vapor chamber device and a semi-open case. The three-dimensional vapor chamber device comprises a plurality of upper covers, a bottom cover, a porous wick structure and a working fluid. Each of the upper covers comprises a base plate and a tube. The base plate has a base cavity, an opening hole, an upper outer surface and an upper internal surface. The tube has a tubular cavity and a tubular internal surface. The tube is configured on the upper outer surface and located above the opening hole and extended outwardly from the upper outer surface. The bottom cover has a bottom internal surface and a bottom outer surface. An airtight cavity is formed from the tubular cavity of the each upper covers and the base cavity when the bottom cover is sealed to the upper covers, and the bottom outer surface of the bottom cover is configured to be contacted with a heat source. The porous wick structure is continuously disposed on the tubular internal surface of the each upper covers, the upper internal surface and the corresponding bottom internal surface. The working fluid is configured in the corresponding airtight cavity, and the pressure of the airtight cavity is less than 1 atm. The semi-open case has an inlet and an outlet. The semi-open case is coupled to the bottom cover of the three-dimensional vapor chamber device to form a heat-exchanging chamber. The inlet and the outlet are connected to the heat-exchanging chamber.

Wherein, the tube further has a top end having a sealed structure, the sealed structure is formed by pre-setting a liquid injection port at the top end, and injecting the working fluid into the airtight cavity through the liquid injection port, and then sealing the liquid injection port.

Wherein, a cold liquid fluid is configured in the heat-exchanging chamber, the inlet and the outlet and the cold liquid fluid is selected from the group consisting of water, acetone, ammonia, methanol, tetrachloroethane, and hydrofluorocarbon chemical refrigerants.

In summary, the liquid-cooling heat-dissipating module with embedded three-dimensional vapor chamber device of the present invention can exchange the high-density heat generated by high-power chips through the condenser area of the three-dimensional vapor chamber device with two-phase flow circulation to enhance the heat dissipation efficiency. Moreover, the plurality of grooves of the bottom cover in the liquid-cooling heat-dissipating module with embedded three-dimensional vapor chamber device of the present invention can reduce the thermal resistance of heat conduction from the heat source to the porous wick structure disposed on the bottom internal surface by reducing the heat conduction distance between the porous wick structure disposed on the bottom cover and the heat source, while taking into account the structural strength of the bottom cover, so as to enhance the heat conduction efficiency. Furthermore, the liquid-cooling heat-dissipating module with embedded three-dimensional vapor chamber device of the present invention can increase the contact area between the condenser area and the cold liquid fluid through the heat dissipation fins disposed on the tube to enhance the heat dissipation efficiency; and increase the heat exchange efficiency with the cold liquid fluid in the heat-exchanging chamber through the flow disturbance structure disposed on the heat dissipation fins generates mixed flow in the heat-exchanging chamber, so as to increase the heat dissipation efficiency. In addition, in the liquid-cooling heat-dissipating module with embedded three-dimensional vapor chamber device of the present invention, the plurality of upper covers of the three-dimensional vapor chamber device can be coupled with the same bottom cover to be contacted with the plurality of heat sources or the same heat source, and dissipate heat in the same heat exchanger, so as to enhance the whole heat dissipation efficiency of the present invention.

### BRIEF DESCRIPTION OF THE APPENDED DRAWINGS

FIG. 1 is a cross-sectional diagram illustrating a liquid-cooling heat-dissipating module with embedded three-dimensional vapor chamber device according to an embodiment of the present invention.

FIG. 2 is a cross-sectional diagram illustrating a three-dimensional vapor chamber device in FIG. 1.

FIG. 3 is a cross-sectional diagram illustrating a three-dimensional vapor chamber device with a plurality of heat dissipation fins disposed on the outer surface of the tube in FIG. 2.

FIG. 4 is a structural schematic diagram illustrating a heat dissipation fin in FIG. 3.

FIG. 5 is a cross-sectional diagram illustrating a liquid-cooling heat-dissipating module with embedded three-dimensional vapor chamber device according to another embodiment of the present invention.

FIG. 6 is a cross-sectional diagram illustrating a liquid-cooling heat-dissipating module with embedded three-dimensional vapor chamber device according to another embodiment of the present invention.

FIG. 7 is a cross-sectional diagram illustrating a liquid-cooling heat-dissipating module with embedded three-dimensional vapor chamber device according to another embodiment of the present invention.

### DETAILED DESCRIPTION OF THE INVENTION

For the sake of the advantages, spirits and features of the present invention can be understood more easily and clearly, the detailed descriptions and discussions will be made later by way of the embodiments and with reference of the diagrams. It is worth noting that these embodiments are merely representative embodiments of the present invention, wherein the specific methods, devices, conditions, materials and the like are not limited to the embodiments of the present invention or corresponding embodiments. Moreover, the devices in the figures are only used to express their corresponding positions and are not drawing according to their actual proportion.

In the description of the presentation, the description with reference to the terms “an embodiment”, “another embodiment” or “part of an embodiment” means that a particular feature, structure, material or characteristic described in connection with the embodiment including in at least one embodiment of the present invention. In the presentation, the schematic representations of the above terms do not necessarily refer to the same embodiment. Furthermore, the particular features, structures, materials or characteristics described may be combined in any suitable manner in one or more embodiments. Furthermore, the indefinite articles “a” and “an” preceding a device or element of the present invention are not limiting on the quantitative requirement (the number of occurrences) of the device or element. Thus, “a” should be read to include one or at least one, and a device or element in the singular also comprises the plural unless the number clearly refers to the singular.

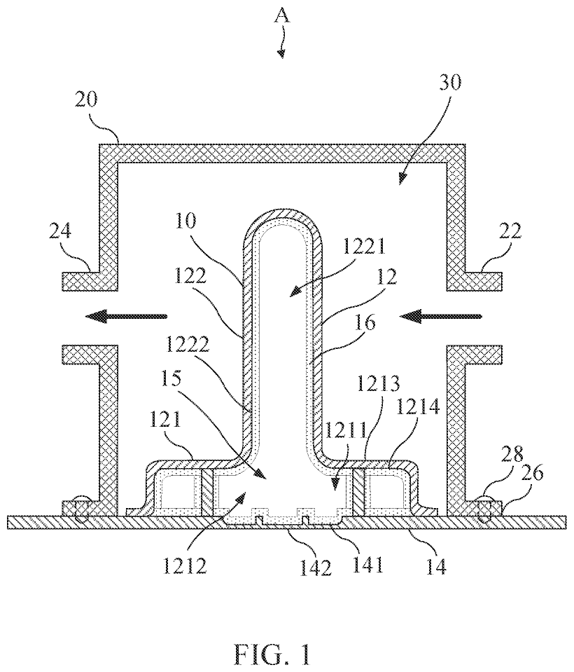

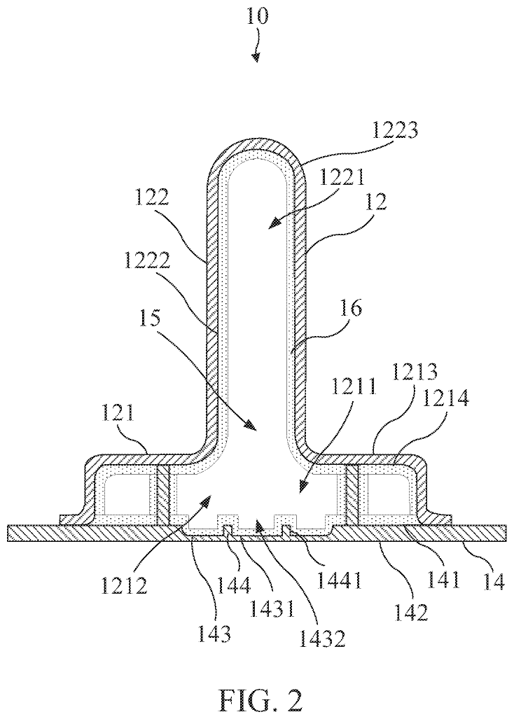

Please refer to FIG. 1 and FIG. 2. FIG. 1 is a cross-sectional diagram illustrating a liquid-cooling heat-dissipating module A with embedded three-dimensional vapor chamber device according to an embodiment of the present invention. FIG. 2 is a cross-sectional diagram illustrating a three-dimensional vapor chamber device 10 in FIG. 1. As shown in FIG. 1 and FIG. 2, in the present embodiment, the liquid-cooling heat-dissipating module A with embedded three-dimensional vapor chamber device comprises a three-dimensional vapor chamber device 10 and a semi-open case 20. The three-dimensional vapor chamber device 10 comprises an upper cover 12, a bottom cover 14, a porous wick structure 16 and a working fluid (not shown). The upper cover 12 has a base plate 121 and a tube 122. The base plate 121 has a base cavity 1211, an opening hole 1212, an upper outer surface 1213 and an upper inner surface 1214. The tube 122 has a tubular cavity 1221 and a tubular internal surface 1222. The tube 122 is configured on the upper outer surface 1213, located above the opening hole 1212 and extended outwardly from the upper outer surface 1213. The bottom cover 14 corresponding to the upper cover 12 has a bottom internal surface 141 and a bottom outer surface 142. An airtight cavity 15 is formed from the base cavity 1211 and the tubular cavity 1221 when the bottom cover 14 is sealed to the upper cover 12. Wherein, the upper cover 12 can be fixedly connected to the bottom cover 14 by gluing, by gluing, welding, etc. The working fluid is configured in the airtight cavity 15, and the pressure of the airtight cavity 15 is less than 1 atm.

As shown in FIG. 1, in the present embodiment, the semi-open case 20 has an inlet 22 and an outlet 24. The semi-open case 20 is coupled to the bottom cover 14 of the three-dimensional vapor chamber device 10 to form a heat-exchanging chamber 30. The inlet 22 and the outlet 24 are connected to the heat-exchanging chamber 30. In practice, the inlet 22 and outlet 24 of the semi-open case 20 are configured opposite at the ends of the semi-open case 20. In an embodiment, the inlet 22 and the outlet 24 can also be configured on the same side of the semi-open case 20. Furthermore, the liquid-cooling heat-dissipating module A with embedded three-dimensional vapor chamber device in the present embodiment can be connected to the bottom internal surface 141 of the bottom cover 14 of the three-dimensional vapor chamber device 10 through the joint end 26 of the semi-open case 20, and fastened to the bottom cover 14 with screws 28. It is also possible to use stirring and friction welding to couple the semi-open case 20 to the three-dimensional vapor chamber device 10 to form a heat-exchanging chamber 30, but in practice, the way in which the semi-open case 20 be coupled to the three-dimensional vapor chamber device 10 is not limited to the aforementioned.

In addition, in practice, the cold liquid fluid (not shown) is configured in the heat-exchanging chamber 30, the inlet 22 and the outlet 24. When the liquid-cooling heat-dissipating module A with embedded three-dimensional vapor chamber device is operating, the cold liquid fluid can flow from the inlet 22 to the heat-exchanging chamber 30 and then flow to the outlet 24 (as shown by the arrow in FIG. 1). In practice, the cold liquid fluid can be water, acetone, ammonia, methanol, tetrachloroethane, and hydrofluorocarbon chemical refrigerants, but is not limited to the above-mentioned, the cold liquid fluid can also be other fluids that absorb heat and carry away heat energy.

As shown in FIG. 2, in the present embodiment, the bottom cover 14 of the three-dimensional vapor chamber device 10 has a plurality of grooves 143, and a groove rib 144 is formed between the grooves 143. The groove rib 144 has a rib surface 1441, and each of the grooves 143 has a groove internal surface 1431 and a groove cavity 1432. The airtight cavity 15 is formed from the base cavity 1211, the tubular cavity 1221 and the groove cavity 1432 when the bottom cover 14 is sealed to the upper cover 12. It is worth noting that in the present embodiment, the shape of the grooves 143 of the bottom cover 14 is square, but it is not limited in practice. The shape and number of the grooves 143 can be designed according to the requirements. Furthermore, the porous wick structure 16 is continuously disposed on the upper internal surface 1214, the bottom internal surface 141, the tubular internal surface 1222, the rib surface 1441 of the groove rib 144 and the groove internal surfaces 1431. The bottom outer surface 142 of the bottom cover 14 is configured to be contacted with a heat source (not shown). Wherein, the heat source can be a chip or chip packaging case of electronic product.

Furthermore, in the present embodiment, the plurality of grooves 143 of the bottom cover 14 in the liquid-cooling heat-dissipating module A with embedded three-dimensional vapor chamber device can reduce the thermal resistance of heat conduction from the heat source to the bottom 14 by reducing the heat conduction distance between the porous wick structure 16 disposed on the bottom cover 14 and the heat source. Since the three-dimensional vapor chamber device 10 has a complete and continuous porous wick structure 16, the working fluid in the porous wick structure 16 of a condenser area 1223 of the tube 122 can smoothly and quickly return to an evaporator area of the bottom cover 14 to make the two-phase flow circulation smooth and further enhance the heat dissipation efficiency.

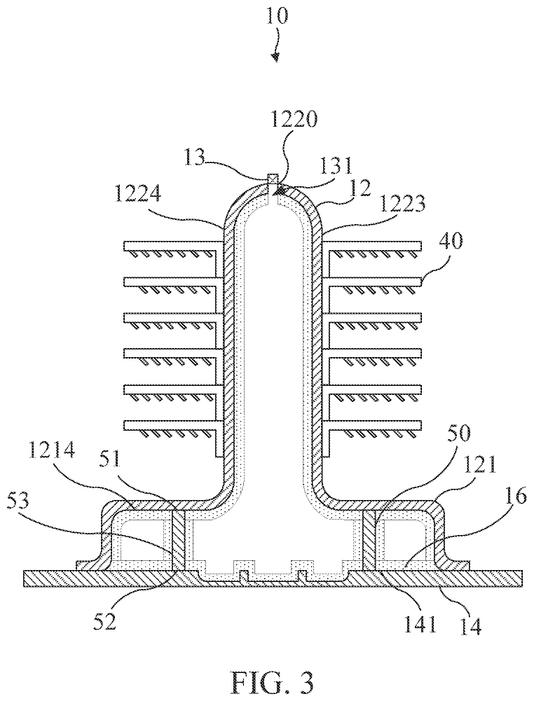

In another embodiment, the tube 122 further has a top end 1220 having a sealed structure 13, and the sealed structure 13 is formed by pre-setting a liquid injection port 131 at the top end 1220, injecting the working fluid into the airtight cavity 15 through the liquid injection port 131, and then sealing the liquid injection port 131. In practice, the liquid injection port 131 can be sealed by welding, etc. Furthermore, the liquid injection port 131 and the sealed structure 13 of the three-dimensional vapor chamber device 10 in the present invention are located at the top end 1220 of the tube 122, but it is not limited in practice, the liquid injection port 131 and the sealed structure 13 can be set at any position on the upper cover 12 instead of the top end 1220 (as shown in FIG. 3).

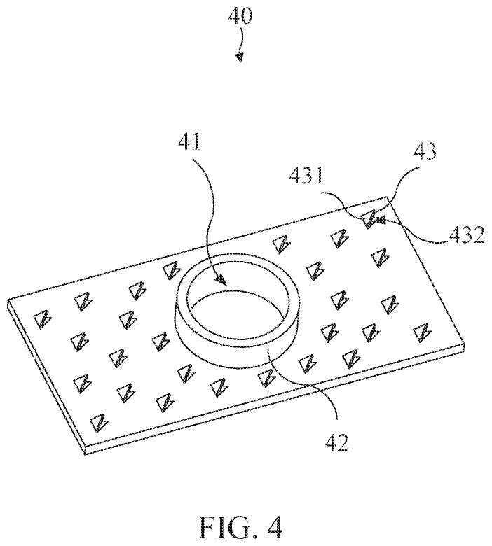

Please refer to FIG. 3 and FIG. 4. FIG. 3 is a cross-sectional diagram illustrating a three-dimensional vapor chamber device 10 with a plurality of heat dissipation fins 40 disposed on the outer surface 1224 of the tube 122 in FIG. 2. FIG. 4 is a structural schematic diagram illustrating a heat dissipation fin 40 in FIG. 3. As shown in FIG. 3 and FIG. 4, in the present embodiment, the three-dimensional vapor chamber device 10 comprises a plurality of heat dissipation fins 40 disposed on the tube 122, and the tube 122 has the condenser area 1223. The heat dissipation fins 40 are coupled to the condenser area 1223 of the tube 122. The heat dissipation fins 40 have a hole 41 and a protruding structure 42. The diameter of the hole 41 can be slightly smaller than the diameter of the tube 122, so the heat dissipation fins 40 can be disposed on the condenser area 1223 of the tube 122 through the hole 41. The protruding structure 42 is positioned around the edges of the hole 41. As shown in FIG. 3, when the plurality of heat dissipation fins 40 are disposed on the tube 122, the protruding structure 42 of the upper heat dissipation fins 40 can hold the lower heat dissipation fins 40, so the plurality of heat dissipation fins 40 can be arranged at a certain spacing. When the heat energy in the gaseous working fluid is transferred to the tube 122, the heat energy can be transferred from the outer surface 1224 of the tube 122 to the heat dissipation fins 40 for heat dissipation. In practice, the number of the heat dissipation fins 40 and the length of the protruding structure 42 can be designed according to the requirements. The heat dissipation fins 40 disposed on the tube 122 of the present embodiment can increase the contact area between the condenser area 1223 and the cold liquid fluid to improve the heat dissipation efficiency.

Furthermore, as shown in FIG. 4, the heat dissipation fin 40 has a plurality of flow disturbance structures 43. The flow disturbance structure 43 has a spoiler 431 and a spoiler opening hole 432. Please refer to FIG. 1 and FIG. 3. In practice, when the liquid-cooling heat-dissipating module A with embedded three-dimensional vapor chamber device carries away the heat energy configured on the condenser area 1223, the cold liquid fluid input from the inlet 22 to the heat-exchanging chamber 30 can generate mixed flow in the heat-exchanging chamber 30 through the flow disturbance structures 43 to increase the heat exchange efficiency with the cold liquid fluid in the heat-exchanging chamber 30, and further enhance the whole dissipation efficiency. It is worth noting that in the present embodiment, the shape of the spoiler 431 and the spoiler opening hole 432 of the flow disturbance structure 43 on the heat dissipation fin 40 is triangular, but it is not limited to the aforementioned in practice. In practice, the shape and number of the flow disturbance structure 43 can be designed according to the requirements.

In the present embodiment, the porous wick structure 16 is continuously disposed on the tubular internal surface 1222, the upper internal surface 1214 and the bottom internal surface 141. In practice, the porous wick structure 16 is disposed by pre-laying a copper-containing powder on the upper internal surface 1214, the bottom internal surface 141 and the tubular internal surface 1222, and after the heat dissipation fins 40 are disposed on the condenser area 1223 of the tube 122, the porous wick structure 16 is continuously disposed on the tubular internal surface 1222, the upper internal surface 1214 and the bottom internal surface 141 and the heat dissipation fins 40 are coupled to the condenser area 1223 of the tube 122 simultaneously by the same sintering process, but it is not limited to the aforementioned in practice. In practice, the porous wick structure 16 can be formed by sintering copper-containing powder or by drying, cracking and sintering slurry.

As shown in FIG. 3, in the present embodiment, the three-dimensional vapor chamber device 10 further comprises a plurality of support columns 50. The support columns 50 has a top end 51 and a bottom end 52, the support column 50 can disposed between the upper internal surface 1214 of the base plate 121 and the bottom internal surface 141 of the bottom cover 14 by welding the top end 51 and the bottom end 52 to the upper internal surface 1214 of the base plate 121 and the bottom internal surface 141 of the bottom cover 14 respectively. In another embodiment, the support column 50 is disposed between the upper internal surface 1214 of the base plate 121 and the bottom internal surface 141 of the bottom cover 14 by a 3D printing process. The support column 50 has a column surface 53. The porous wick structure 16 continuously disposed on the upper internal surface 1214, the bottom internal surface 141, the tubular internal surface 1222 and the column surface 53. Thus, the porous wick structure 16 disposed on the column surface 53 can also assist the working fluid to flow back to the porous wick structure 16 disposed on the bottom internal surface 141 of the bottom cover 14. Furthermore, when extracting air from the airtight cavity 15, the support column 50 can prevent the bottom cover 14 from being depressed or deformed due to the lower pressure of the airtight cavity 15, so the bottom outer surface 142 of the bottom cover 14 can be contacted with the heat source flatly and tightly, which reduces the contact thermal resistance, and further enhances the heat-dissipating efficiency. It is worth noting that the number of the support columns 50 in FIG. 3 is only two. In practice, the number of the support columns 50 can be determined according to the requirements, the length of the support columns 50 can correspond to the height of the base cavity 1211, and the support columns 50 can be encircled around the opening hole 1212 of the base plate 121.

As shown in FIG. 1 to FIG. 3, when the liquid-cooling heat-dissipating module A with embedded three-dimensional vapor chamber device operates, the bottom outer surface 142 of the bottom cover 14 will absorb the heat energy generated by the heat source. At this time, the liquid working fluid in the porous wick structure 16 of the bottom internal surface 141 also absorbs the heat energy and converts to gaseous working fluid, and the gaseous working fluid will carry the heat energy to the condenser area 1223 of the tube 122, and exchange heat with the cold liquid fluid in the heat-exchanging chamber 30. Further, the cold liquid fluid flowing from the inlet 22 of the semi-open case 20 will absorb the heat energy from the condenser area 1223. At this time, the gaseous working fluid in the three-dimensional vapor chamber device 10 is converted to liquid working fluid at the condenser area 1223, and the liquid working fluid flows back to the porous wick structure 16 disposed on the bottom internal surface 141 of the bottom cover 14 through the porous wick structure 16. Next, the cold liquid fluid with the heat energy flows out from the outlet 24 of the semi-open case 20 to carry away the heat energy from the heat source for heat dissipation. Therefore, the liquid-cooling heat-dissipating module with embedded three-dimensional vapor chamber device in the present invention can directly exchange heat with the cold liquid fluid in the heat-exchanging chamber through the condenser area of the three-dimensional vapor chamber device, so as to enhance the heat dissipation efficiency.

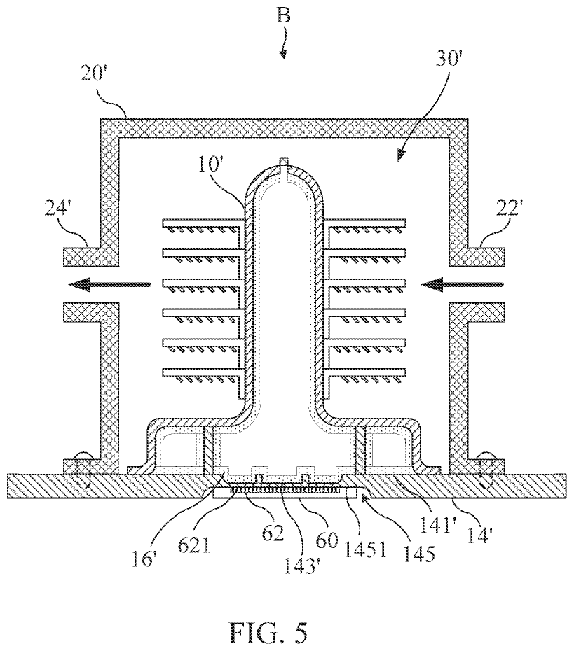

Please refer to FIG. 5. FIG. 5 is a cross-sectional diagram illustrating a liquid-cooling heat-dissipating module B with embedded three-dimensional vapor chamber device according to another embodiment of the present invention. In the present embodiment, the bottom cover 14′ of the three-dimensional vapor chamber device 10′ further comprises a bottom groove 145 configured to accommodate a circuit board 60 with a chip 62, a chip surface 621 of the chip 62 is contacted with a bottom groove surface 1451 of the bottom groove 145. In practice, when the circuit board 60 does not fit completely and tightly in the bottom groove 145 of the bottom cover 14′, the gap between the circuit board 60 and the bottom groove 145 can be filled with thermal gel to make the circuit board 60 and the bottom groove 145 fit more tightly and reduce the heat conduction efficiency from the contact thermal resistance. When the liquid-cooling heat-dissipating module B with embedded three-dimensional vapor chamber device operates, the cold liquid fluid can flow from the inlet 22′ of the semi-open case 20′ to the heat-exchanging chamber 30′ and from the heat-exchanging chamber 30′ to the outlet 24′ of the semi-open case 20′ (as shown by the arrow in FIG. 5). In addition, in the present embodiment, the groove 143′ of the bottom cover 14′ and the bottom groove 145 in the three-dimensional vapor chamber device 10′ can reduce the heat conduction distance between the chip 62 and the porous wick structure 16′, and reduce the thermal resistance of the heat energy generated by the chip 62 during operation to the porous wick structure 16′ on the bottom internal surface 141′ of the bottom cover 14′, so as to enhance the heat conduction efficiency. It should be noted that the liquid-cooling heat-dissipating module B with embedded three-dimensional vapor chamber device of the present embodiment has substantially the same structure and function as the corresponding element of the aforementioned embodiment, so it will not be described again herein.

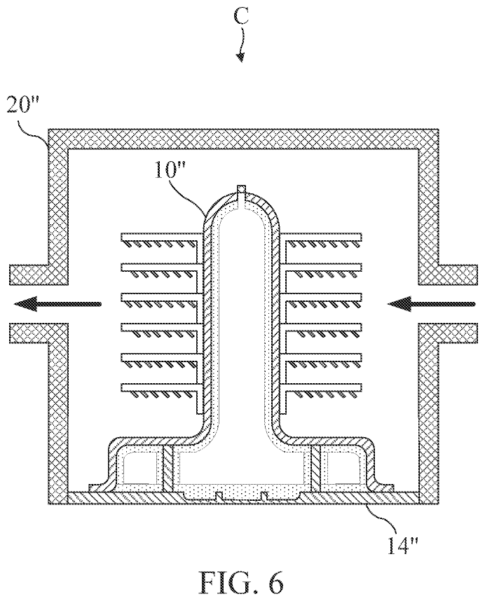

Please refer to FIG. 6. FIG. 6 is a cross-sectional diagram illustrating a liquid-cooling heat-dissipating module C with embedded three-dimensional vapor chamber device according to another embodiment of the present invention. The liquid-cooling heat-dissipating module C with embedded three-dimensional vapor chamber device of the present embodiment differs from the aforementioned embodiment in that the three-dimensional vapor chamber device 10″ and the semi-open case 20″ in the present embodiment are coupled by gluing, welding and stirring friction welding to seal the bottom cover 14″ of the three-dimensional vapor chamber device 10″ to the semi-open case 20″. Wherein, the length of the bottom cover 14″ of the three-dimensional vapor chamber device 10″ can be equal to or slightly smaller than the width of the semi-open case 20″, so the semi-open case 20″ and three-dimensional vapor chamber device 10″ can form the sealed liquid-cooling heat-dissipating module C with embedded three-dimensional vapor chamber device. It should be noted that the liquid-cooling heat-dissipating module C with embedded three-dimensional vapor chamber device of the present embodiment has substantially the same structure and function as the corresponding element of the aforementioned embodiment, so it will not be described again herein. Furthermore, in practice, the length of the bottom cover of the three-dimensional vapor chamber device, the width of the semi-open case, and the coupling method between the three-dimensional vapor chamber device and the semi-open case are not limited to the aforementioned.

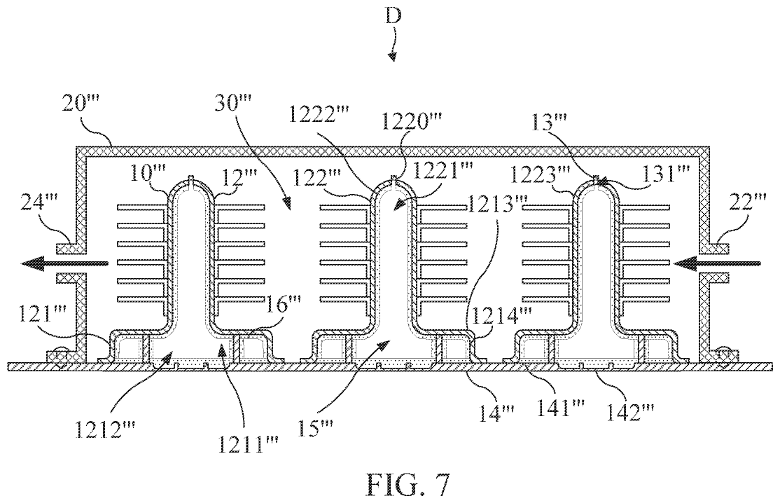

The liquid-cooling heat-dissipating module with embedded three-dimensional vapor chamber device of the present invention can be not only in the aforementioned form, but also in other forms. Please refer to FIG. 7. FIG. 7 is a cross-sectional diagram illustrating a liquid-cooling heat-dissipating module D with embedded three-dimensional vapor chamber device according to another embodiment of the present invention. In the present embodiment, the liquid-cooling heat-dissipating module D with embedded three-dimensional vapor chamber device comprises a three-dimensional vapor chamber device 10′″ and a semi-open case 20′″. The three-dimensional vapor chamber device 10′″ comprises a plurality of upper covers 12′″, a bottom cover 14′″, a porous wick structure 16′″ and a working fluid (not shown). Each of the upper covers 12′″ comprises a base plate 121′ and a tube 122′″. The base plate 121′″ has a base cavity 1211′″, an opening hole 1212′″, an upper outer surface 1213′″ and an upper internal surface 1214′″. The tube 122′″ has a tubular cavity 1221′″ and a tubular internal surface 1222′″. The tube 122′″ is configured on the upper outer surface 1213″ and located above the opening hole 1212′″ and extended outwardly from the upper outer surface 1213″. The bottom cover 14′ has a bottom internal surface 141′″ and a bottom outer surface 142′″. An airtight cavity 15″ is formed from the tubular cavity 1221′″ of the each upper covers 12′″ and the base cavity 1211′″ when the bottom cover 14′″ is sealed to the upper covers 12′″. The bottom outer surface 142′″ of the bottom cover 14′″ is configured to be contacted with a heat source. The porous wick structure 16′″ is continuously disposed on the tubular internal surface 1222′″ of the each upper covers 12′″, the upper internal surface 1214′″ and the corresponding bottom internal surface 141′″. Wherein, the working fluid is configured in the corresponding airtight cavity 15′″, and the pressure of the airtight cavity 15″ is less than 1 atm.

In the present embodiment, the tube 122′″ further has a top end 1220′ having a sealed structure 13′″, and the sealed structure 13′″ is formed by pre-setting a liquid injection port 131′ at the top end 1220′″, and injecting the working fluid into the airtight cavity 15″ through the liquid injection port 131′″, and then sealing the liquid injection port 131′″. In practice, the liquid injection port 131′″ can be sealed by welding, etc. Furthermore, the liquid injection port 131′″ and the sealed structure 13′″ of the three-dimensional vapor chamber device 10′″ in the present invention are located at the top end 1220′″ of the tube 122′″, but it is not limited in practice, the liquid injection port 131′″ and the sealed structure 13′″ can be set at any position on the upper cover 12′″ instead of the top end 1220′. The semi-open case 20′″ has an inlet 22′″ and an outlet 24′″. The semi-open case 20′″ is coupled to the bottom cover 14′″ to form a heat-exchanging chamber 30′″. The inlet 22′″ and the outlet 24′″ are connected to the heat-exchanging chamber 30′″. In practice, a cold liquid fluid is configured in the heat-exchanging chamber 30′″, the inlet 22′″ and the outlet 24′″ and the cold liquid fluid is selected from the group consisting of water, acetone, ammonia, methanol, tetrachloroethane, and hydrofluorocarbon chemical refrigerants, but is not limited to the above-mentioned, the cold liquid fluid can also be other fluids that absorb heat and carry away heat energy.

As shown in FIG. 7, the liquid-cooling heat-dissipating module D with embedded three-dimensional vapor chamber device of the present embodiment differs from the aforementioned embodiment in that the three upper covers 12′″ of the three-dimensional vapor chamber device 10′″ in the present embodiment can be coupled with the same bottom cover 14′″, can be contacted with three different heat sources separately or be contacted with the same heat source simultaneously, and exchange heat in the same heat-exchanging chamber 30′″. In practice, the three upper covers 12′″ of the three-dimensional vapor chamber device 10′″ can be arranged in the same heat-exchanging chamber 30′″ in parallel and in other ways. Wherein, the upper cover 12′″ can be fixedly connected to the bottom cover 14′″ by gluing, by gluing, welding, etc.

When the liquid-cooling heat-dissipating module D with embedded three-dimensional vapor chamber device operates, the cold liquid fluid can flow from the inlet 22′″ to the heat-exchanging chamber 30′″, carry the heat energy from the condenser area 1223′″ disposed on the different upper covers 12′″ through the different upper covers 12′″, and flow from the heat-exchanging chamber 30′″ to the outlet 24′″ (as shown by the arrow in FIG. 7). In practice, the number and arrangement of the upper covers 12′″ can be designed according to the requirements. It should be noted that the liquid-cooling heat-dissipating module D with embedded three-dimensional vapor chamber device of the present embodiment has substantially the same structure and function as the corresponding element of the aforementioned embodiment, so it will not be described again herein. Therefore, in the liquid-cooling heat-dissipating module with embedded three-dimensional vapor chamber device of the present invention, the plurality of upper covers of the three-dimensional vapor chamber device can be coupled with the same bottom cover to be contacted with the plurality of heat sources or the same heat source, and dissipate heat in the same heat exchanger, so as to enhance the whole heat dissipation efficiency of the liquid-cooling heat-dissipating module with embedded three-dimensional vapor chamber device.

In summary, the liquid-cooling heat-dissipating module with embedded three-dimensional vapor chamber device of the present invention can exchange the high-density heat generated by high-power chips through the condenser area of the three-dimensional vapor chamber device with two-phase flow circulation to enhance the heat dissipation efficiency. Moreover, the plurality of grooves of the bottom cover in the liquid-cooling heat-dissipating module with embedded three-dimensional vapor chamber device of the present invention can reduce the thermal resistance of heat conduction from the heat source to the porous wick structure disposed on the bottom internal surface by reducing the heat conduction distance between the porous wick structure disposed on the bottom cover and the heat source, while taking into account the structural strength of the bottom cover, so as to enhance the heat conduction efficiency. Furthermore, the liquid-cooling heat-dissipating module with embedded three-dimensional vapor chamber device of the present invention can increase the contact area between the condenser area and the cold liquid fluid through the heat dissipation fins disposed on the tube to enhance the heat dissipation efficiency; and increase the heat exchange efficiency with the cold liquid fluid in the heat-exchanging chamber through the flow disturbance structure disposed on the heat dissipation fins generates mixed flow in the heat-exchanging chamber, so as to increase the heat dissipation efficiency. In addition, in the liquid-cooling heat-dissipating module with embedded three-dimensional vapor chamber device of the present invention, the plurality of upper covers of the three-dimensional vapor chamber device can be coupled with the same bottom cover to be contacted with the plurality of heat sources or the same heat source, and dissipate heat in the same heat exchanger, so as to enhance the whole heat dissipation efficiency of the present invention.

With the examples and explanations mentioned above, the features and spirits of the invention are hopefully well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A liquid-cooling heat-dissipating module with embedded three-dimensional vapor chamber device, comprising:
a three-dimensional vapor chamber device, comprising:
an upper cover, comprising a base plate and a tube, the base plate having a base cavity, an opening hole, an upper outer surface and an upper internal surface, the tube having a tubular cavity and a tubular internal surface, and the tube being configured on the upper outer surface and located above the opening hole and extended outwardly from the upper outer surface;
a bottom cover, corresponding to the upper cover and having a bottom internal surface and a bottom outer surface, an airtight cavity formed from the base cavity and the tubular cavity when the bottom cover is sealed to the upper cover, and the bottom outer surface of the bottom cover configured to be contacted with a heat source;
a porous wick structure, continuously disposed on the tubular internal surface, the upper internal surface and the bottom internal surface; and
a working fluid, configured in the airtight cavity, and the pressure of the airtight cavity less than 1 atm; and
a semi-open case, having an inlet and an outlet, the semi-open case coupled to the bottom cover of the three-dimensional vapor chamber device to form a heat-exchanging chamber, and the inlet and the outlet connected to the heat-exchanging chamber.

2. The liquid-cooling heat-dissipating module with embedded three-dimensional vapor chamber device of claim 1, wherein the tube further has a top end having a sealed structure, and the sealed structure is formed by pre-setting a liquid injection port at the top end, and injecting the working fluid into the airtight cavity through the liquid injection port, and then sealing the liquid injection port, and a cold liquid fluid is configured in the heat-exchanging chamber, the inlet and the outlet and the cold liquid fluid is selected from the group consisting of water, acetone, ammonia, methanol, tetrachloroethane, and hydrofluorocarbon chemical refrigerants.

3. The liquid-cooling heat-dissipating module with embedded three-dimensional vapor chamber device of claim 1, wherein the bottom cover has a plurality of grooves, and a groove rib is formed between the grooves, the groove rib has a rib surface, and each of the grooves has a groove internal surface and a groove cavity.

4. The liquid-cooling heat-dissipating module with embedded three-dimensional vapor chamber device of claim 3, wherein the porous wick structure is continuously disposed on the upper internal surface, the bottom internal surface, the tubular internal surface, the rib surface of the groove rib and the groove internal surfaces.

5. The liquid-cooling heat-dissipating module with embedded three-dimensional vapor chamber device of claim 1, wherein the three-dimensional vapor chamber device further comprises a plurality of heat dissipation fins, the tube further comprises a condenser area, and the heat dissipation fins coupled to the condenser area of the tube.

6. The liquid-cooling heat-dissipating module with embedded three-dimensional vapor chamber device of claim 5, wherein the porous wick structure is disposed by pre-laying a copper-containing powder on the upper internal surface, the bottom internal surface and the tubular internal surface, and after the heat dissipation fins are disposed on the condenser area of the tube, the porous wick structure is continuously disposed on the tubular internal surface, the upper internal surface and the bottom internal surface and the heat dissipation fins are coupled to the condenser area simultaneously by the same sintering process.

7. The liquid-cooling heat-dissipating module with embedded three-dimensional vapor chamber device of claim 1, wherein the three-dimensional vapor chamber device further comprises a plurality of support columns disposed between the upper internal surface of the base plate and the bottom internal surface of the bottom cover, each of the support columns has a column surface, and the porous wick structure continuously disposed on the upper internal surface, the bottom internal surface, the tubular internal surface and the column surface.

8. The liquid-cooling heat-dissipating module with embedded three-dimensional vapor chamber device of claim 1, wherein the bottom cover further comprises a bottom groove configured to accommodate a circuit board with a chip, a chip surface of the chip is contacted with a bottom groove surface of the bottom groove.

9. A liquid-cooling heat-dissipating module with embedded three-dimensional vapor chamber device, comprising:
a three-dimensional vapor chamber device, comprising:
a plurality of upper covers, each of the upper covers comprising a base plate and a tube, the base plate having a base cavity, an opening hole, an upper outer surface and an upper internal surface, the tube having a tubular cavity and a tubular internal surface, and the tube being configured on the upper outer surface and located above the opening hole and extended outwardly from the upper outer surface;
a bottom cover, having a bottom internal surface and a bottom outer surface, an airtight cavity formed from the tubular cavity of the each upper covers and the base cavity when the bottom cover is sealed to the upper covers, and the bottom outer surface of the bottom cover configured to be contacted with a heat source;
a porous wick structure, continuously disposed on the tubular internal surface of the each upper covers, the upper internal surface and the bottom internal surface; and
a working fluid, configured in the airtight cavity, the pressure of the airtight cavity less than 1 atm; and
a semi-open case, having an inlet and an outlet, the semi-open case coupled to the bottom cover of the three-dimensional vapor chamber device to form a heat-exchanging chamber, and the inlet and the outlet connected to the heat-exchanging chamber.

10. The liquid-cooling heat-dissipating module with embedded three-dimensional vapor chamber device of claim 9, wherein the tube further has a top end having a sealed structure, the sealed structure is formed by pre-setting a liquid injection port at the top end, and injecting the working fluid into the airtight cavity through the liquid injection port, and then sealing the liquid injection port, and a cold liquid fluid is configured in the heat-exchanging chamber, the inlet and the outlet and the cold liquid fluid is selected from the group consisting of water, acetone, ammonia, methanol, tetrachloroethane, and hydrofluorocarbon chemical refrigerants.
